(19) United States
(12) Patent Application Publication
(10) Pub. No.: US 2024/0286314 A1
(43) Pub. Date: Aug. 29, 2024

(54) METAL WIRE AND SAW WIRE

(71) Applicant: Panasonic Intellectual Property Management Co., Ltd., Osaka (JP)

(72) Inventors: Tomohiro KANAZAWA, Osaka (JP); Kenshi TSUJI, Osaka (JP); Yui NAKAI, Osaka (JP); Tetsuya NAKAAZE, Osaka (JP)

(73) Assignee: Panasonic Intellectual Property Management Co., Ltd., Osaka (JP)

(21) Appl. No.: 18/572,811

(22) PCT Filed: Jun. 30, 2022
(86) PCT No.: PCT/JP2022/026355

§ 371 Date: Dec. 21, 2023

(30) Foreign Application Priority Data
Jul. 15, 2021 (JP) 2021-117418

(51) Int. Cl. B28D 5/04; B28D 5/00; G01N 3/32

(52) U.S. Cl. CPC B28D 5/045; G01N 3/32; B28D 5/0082; G01N 2203/0067; G01N 2203/0073

(57) ABSTRACT

A metal wire includes tungsten or a tungsten alloy. When a fatigue test is conducted on the metal wire at a maximum stress of 4400 MPa in accordance with Japanese Industrial Standard (JIS) C6821, a total number of cycles required to break the metal wire is at least 20,000 cycles.

### TECHNICAL FIELD

The present invention relates to a metal wire and a saw wire.

### BACKGROUND ART

Patent Literature (PTL) 1 discloses a saw wire including a core wire made of a piano wire and abrasive particles fixed to the core wire.

### CITATION LIST

### Patent Literature

[PTL 1] Japanese Unexamined Patent Application Publication No. 2018-65205

### SUMMARY OF INVENTION

### Technical Problem

The conventional saw wire is not sufficiently durable.

Therefore, an object of the present invention is to provide a highly durable metal wire and a highly durable saw wire.

### Solution to Problem

A metal wire according to one aspect of the present invention includes tungsten or a tungsten alloy. When a fatigue test is conducted on the metal wire at a maximum stress of 4400 MPa in accordance with Japanese Industrial Standard (JIS) C6821, a total number of cycles required to break the metal wire is at least 20,000 cycles.

A saw wire according to one aspect of the present invention includes: the metal wire according to the one aspect; and abrasive particles electrodeposited on a surface of the metal wire.

### Advantageous Effects of Invention

The present invention can provide a highly durable metal wire and a highly durable saw wire.

### BRIEF DESCRIPTION OF DRAWINGS

FIG. 1 is a schematic diagram of a cutting device to which a saw wire according to an embodiment is attached.

FIG. 2 is a schematic diagram of a testing device used in a fatigue test for the metal wire according to the embodiment.

FIG. 3A is a side perspective view of a jig of the testing device illustrated in FIG. 2.

FIG. 3B is a bottom perspective view of the jig of the testing device illustrated in FIG. 2.

FIG. 4 is a graph showing results of the fatigue test.

FIG. 5A is a cross-sectional view of a metal wire according to Working Example 1.

FIG. 5B is a cross-sectional view of a metal wire according to Working Example 2.

FIG. 5C is a cross-sectional view of a metal wire according to Working Example 3.

FIG. 5D is a cross-sectional view of a metal wire according to Working Example 4.

FIG. 6 is a flowchart illustrating a method of manufacturing a metal wire according to the embodiment.

### DESCRIPTION OF EMBODIMENTS

The following describes in detail a metal wire and a saw wire according to an embodiment of the present invention, with reference to the drawings. Note that each of the embodiments described below shows a specific example of the present invention. As such, the numerical values, shapes, materials, structural elements, the arrangement and connection of the structural elements, steps, the processing order of the steps, and so on, shown in the following embodiments are mere examples, and therefore do not limit the present invention. Therefore, among the structural elements in the embodiments described below, structural elements not recited in the independent claims will be described as optional structural elements.

In addition, figures are schematic illustrations and are not necessarily precise depictions. Accordingly, for example, the figures are not necessarily to scale. Moreover, in the figures, structural elements that are essentially the same share like reference signs. Accordingly, duplicate description is omitted or simplified.

Moreover, in the present specification, terms representing relationships between structural elements such as perpendicular, terms describing the shapes of structural elements such as circular or cylindrical, and numerical ranges include, not only the precise meanings, but also substantially equal ranges including, for example, a difference of approximately a few or several percent.

### Embodiment

### [Configurations of Metal Wire and Saw Wire]

First, configurations of a metal wire and a saw wire according to the present embodiment will be described.

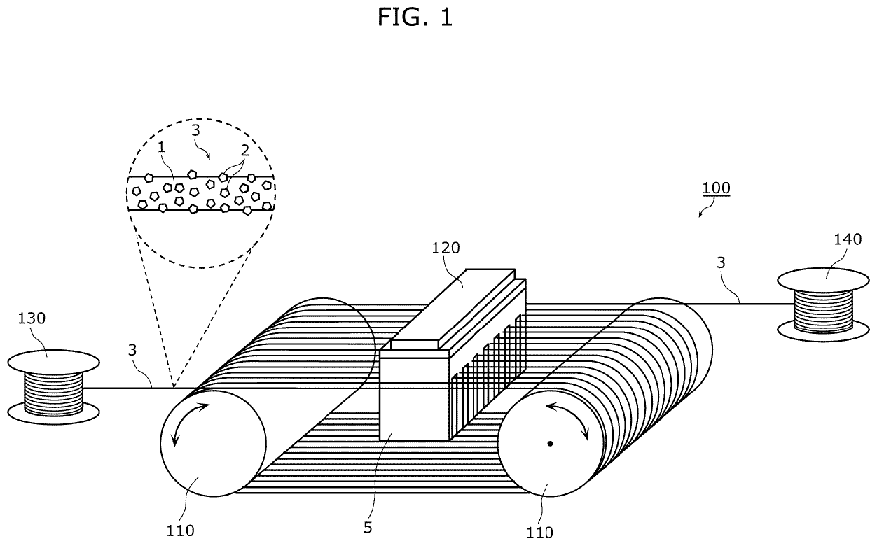

FIG. 1 is a schematic diagram of cutting device 100 to which saw wire 3 according to the present embodiment is attached. Saw wire 3 is attached to cutting device 100 and is used to cut ingot 5. As illustrated in the enlarged view shown in the dashed circle in FIG. 1, saw wire 3 includes metal wire 1 and abrasive particles 2.

Metal wire 1 is a core wire of saw wire 3. Metal wire 1 contains tungsten or a tungsten alloy. The tungsten content of metal wire 1 is, for example, but not limited to, at least 90 wt %. Note that the tungsten content of metal wire 1 may be at least 95 wt %, at least 99 wt %, at least 99.9 wt %, or 99.99 wt %. Metal wire 1 may include inevitable impurities that cannot be avoided from being mixed during the manufacturing process.

The tungsten alloy is, for example, an alloy containing tungsten (W) and at least one type of metal other than tungsten. An example of metals other than tungsten is rhenium (Re). The rhenium content of metal wire 1 containing a rhenium tungsten alloy (ReW) is, for example, but not limited to, at least 0.1 wt % and at most 10 wt %. For example, the rhenium content may be at least 1 wt %, at least 3 wt %, or at least 5 wt %.

When the rhenium content is high, the tensile strength of metal wire 1 can be increased. On the other hand, when the rhenium content is too high, it is difficult to thin metal wire 1 while maintaining a high tensile strength of metal wire 1. More specifically, breakage is more likely to occur, making it difficult to draw metal wire 1 in a long length. By lowering the rhenium content and increasing the tungsten content to 90 wt % or more, the workability of metal wire 1 can be improved. Moreover, by reducing the content of rare and expensive rhenium, it is possible to mass-produce inexpensive metal wires 1 in long lengths.

Note that the metal used in the alloy with tungsten may be osmium (Os), ruthenium (Ru), or iridium (Ir). The content of osmium, ruthenium, or iridium is equal to the content of rhenium, for example. In these cases, similar effects can be obtained as in the case of the rhenium tungsten alloy. Metal wire 1 may contain an alloy of tungsten and at least two types of metals other than tungsten.

Metal wire 1 has a substantially circular cross-sectional shape in the cross-section perpendicular to the axis direction. Note that the axis direction is a direction in which metal wire 1 extends. The diameter of metal wire 1 is substantially constant in the axis direction. The diameter of metal wire 1 is, for example, but not limited to, at most 100 μm. The diameter of metal wire 1 may be at most 80 μm, at most 60 μm, at most 50 μm, at most 40 μm, at most 30 μm, at most 20 μm, or at most 10 μm.

The diameter of saw wire 3 decreases as the diameter of metal wire 1 decreases. When the diameter of saw wire 3 is reduced, the cutting allowance of an object to be cut decreases. Therefore, it is possible to reduce a kerf loss of the object to be cut and increase the number of wafers that can be obtained.

Note that the diameter of metal wire 1 is, for example, at least 5 μm. This ensures that the cross-sectional area of metal wire 1 will not be too small and ensures the absolute strength of metal wire 1 within a range available as a saw wire.

Metal wire 1 has a tensile strength of at least 4800 MPa (=4.8 GPa). The tensile strength may be at least 5000 MPa, at least 5200 MPa, at least 5500 MPa, or at least 5700 MPa. The tensile strength may be, for example, at most 6000 MPa, but may be greater than 6000 MPa. The tensile strength can be measured, for example, in accordance with the tensile test (JIS H 4460 8) of the Japanese Industrial Standard.

Metal wire 1 (saw wire 3) can be stretched more strongly on the guide roller as the tensile strength of metal wire 1 increases, and thus the oscillation width of metal wire 1 can be reduced. When the oscillation width of metal wire 1 is reduced, the cutting allowance of an object to be cut decreases. This makes it possible to reduce a kerf loss of an object to be cut.

When a fatigue test is conducted on metal wire 1 according to the present embodiment at a maximum stress of 4400 MPa in accordance with JIS C6821, a total number of cycles required to break metal wire 1 is at least 20,000 cycles. That is, metal wire 1 has excellent durability. A specific fatigue test will be described later.

Abrasive particles 2 are hard particles, and are, for example, particles of a diamond or cubic boron nitride (CBN). Abrasive particles 2 are dispersed and provided on the surface of metal wire 1. The average particle size of abrasive particles 2 is, for example, at most 10 μm. Abrasive particles 2 are dispersed and provided on the entire surface of metal wire 1 over the entire circumference around the axis of metal wire 1.

Abrasive particles 2 are electrodeposited on the surface of metal wire 1. More specifically, at least of part of abrasive particles 2 is covered by a plating layer (not illustrated), and thus abrasive particles 2 are adhered to the surface of metal wire 1. The plating layer is, for example, a metal layer made of a single substance of nickel or an alloy layer made of nickel. The plating layer may have a multi-layered structure.

### [Configuration and Operation of Cutting Device]

Next, the configuration and operation of cutting device 100 will be described.

As illustrated in FIG. 1, cutting device 100 is a multi-wire saw device to which saw wire 3 is attached. Cutting device 100 manufactures wafers (substrates) by cutting (slicing) ingot 5 into thin plates. Ingot 5 is an example of an object to be cut by cutting device 100, and an ingot of semiconductor, such as silicon or silicon carbide, for example. Note that the object to be cut may be, but not limited to, semiconductor ingots, but include solid products (lumps) made of various solid materials, such as metals, resins, glass, or concrete.

Cutting device 100 includes saw wire 3, two guide rollers 110, support 120, unwinder 130, and winder 140, as illustrated in FIG. 1.

A single saw wire 3 is wound around the two guide rollers 110 a plurality of times. Saw wire 3 is repeatedly wound around the two guide rollers 110 alternately, from unwinder 130 to winder 140. Each of the two guide rollers 110 includes grooves provided at predetermined intervals for saw wire 3 to fit in. The interval between the grooves is determined according to the thickness of wafers desired to be sliced off. The width of each groove is substantially the same as the diameter of saw wire 3. Saw wire 3 is wrapped around the two guide rollers 110 a plurality of times parallel to one another at equal spacing. When the two guide rollers 110 rotate, saw wire 3 rotates in conjunction with the rotation.

Support 120 supports ingot 5, which is an object to be cut. Support 120 can be moved (downward in the figure) toward saw wire 3 while supporting ingot 5.

Unwinder 130 includes a winding frame around which saw wire 3 is wound, and saw wire 3 is unwound from the winding frame in accordance with the rotation of guide rollers 110.

Winder 140 includes a winding frame for winding saw wire 3 and winds saw wire 3 around the winding frame in accordance with the rotation of guide rollers 110.

Next, an operation of cutting ingot 5 by cutting device 100 will be described.

When cutting ingot 5, cutting device 100 rotates each of the two guide rollers 110 to which saw wire 3 is attached. Saw wire 3 rotates in conjunction with the rotation of guide rollers 110 with being stretched with a predetermined tension in a straight line. The predetermined tension is, for example, 3600 MPa.

Ingot 5 is cut (sliced) by saw wire 3 as a result of support 120 pushing ingot 5 toward saw wire 3. When cutting, saw wire 3 is subjected to a momentary stress of up to approximately 4400 MPa.

Note that guide rollers 110 can rotate not only in the direction from unwinder 130 toward winder 140 (positive rotation), but also in the opposite direction (reverse rotation). Guide rollers 110 gradually move saw wire 3 from unwinder 130 to winder 140, by repeating the positive rotation and the reverse rotation when ingot 5 is cut.

Due to this rotation and movement, saw wire 3 is bent and stretched thousands of times during a single cut. For this reason, when a non-durable piano wire is used as a saw wire, such a piano wire will fatigue fracture after the single cut. Even if the piano wire does not fatigue fracture, it is necessary to prepare a new piano wire, because it will not withstand a second cut.

In contrast, when a fatigue test is conducted on saw wire 3 according to the present embodiment at a maximum stress of 4400 MPa in accordance with Japanese Industrial Standard JIS C6821, a total number cycles required to break metal wire 1 is at least 20,000 cycles. In other words, saw wire 3 is less likely to fatigue fracture even when ingot 5 is cut and can be reused for the second and subsequent cuts.

Note that when saw wire 3 is reused, the worn abrasive particles 2 and the plating layer may be peeled off. In other words, after saw wire 3 is returned to the state of metal wire 1 (bare wire), abrasive particles 2 are adhered to the surface of metal wire 1 again by electrodeposition. With this, saw wire 3 having abrasive particles 2 adhered thereto is manufactured again and can be reused to cut ingot 5.

### [Fatigue Test]

Next, a fatigue test conducted by the inventors of the present application to check the durability of metal wire 1 according to the present embodiment will be described.

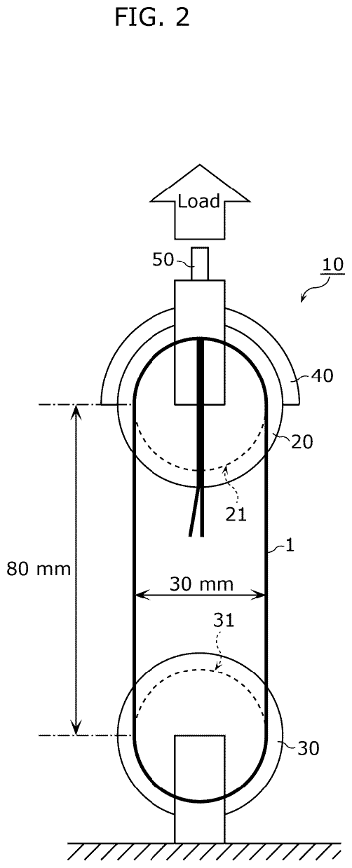

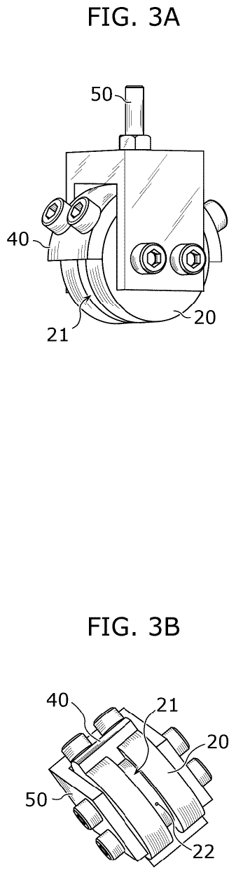

The fatigue test was conducted in accordance with JIS C6821 (Test methods for mechanical characteristics of optical fibers). FIG. 2 is a schematic diagram of testing device 10 used in the fatigue test for metal wire 1 according to the present embodiment. FIG. 3A is a side perspective view of jig 20 of testing device 10 illustrated in FIG. 2, and FIG. 3B is a bottom perspective view of jig 20 of testing device 10 illustrated in FIG. 2.

As illustrated in FIG. 2, testing device 10 includes jigs 20 and 30, cover 40, and hoisting tool 50.

Each of jigs 20 and 30 is a disc-shaped member having a predetermined thickness. Jig 20 includes groove 21 along the circumferential side surface. Jig 30 includes groove 31 along the circumferential side surface. Jig 30 is, for example, fixed on the floor (ground). Hoisting tool 50 is fixed on jig 20. Hoisting tool 50 can apply a vertical upward load to jig 20.

In the fatigue test, metal wire 1 having a predetermined length is placed such that metal wire 1 is wrapped around jig 20 and jig 30 once. More specifically, as illustrated in FIG. 2, metal wire 1 is placed in groove 21 of jig 20 and groove 31 of jig 30. As illustrated in FIG. 3B, groove 21 includes through hole 22 into which metal wire 1 can be inserted. As illustrated in FIG. 2, both ends of metal wire 1 are inserted into through hole 22. In this state, as illustrated in FIG. 3A, cover 40 is fixed to jig 20 to cover groove 21 and fix metal wire 1.

The diameter of each of groove 21 of jig 20 and groove 31 of jig 30 is 30 mm. Therefore, the distance between the suspended parts of metal wire 1 is 30 mm. In addition, the length of each of the suspended parts of metal wire 1, that is, the length of each of the parts of metal wire 1 between jig 20 and jig 30, was 80 mm.

In the fatigue test, as illustrated in FIG. 2, metal wire 1 is fixed and jig 20 is repeatedly subjected to a vertical upward load, and the total number cycles required to fracture metal wire 1, i.e., break metal wire 1, was counted. By applying a load to jig 20, metal wire 1 is subjected to stress. Applying the load from a predetermined initial value to a maximum value is counted as one cycle of the test. The initial value is 10% of the maximum load. The test frequency, that is, a total number of cycles per second, was 10 Hz (=10 cycles per second).

The maximum load is a value at which the stress (i.e., maximum stress) to be applied to metal wire 1 is 4400 MPa when the maximum load is applied. This value corresponds to the maximum stress that can be applied to saw wire 3 (metal wire 1) when saw wire 3 (metal wire 1) attached to cutting device 100 cuts ingot 5. Note that it is not necessary to apply a maximum stress of 4400 MPa precisely, and there may be a deviation of a few or several percent.

The metal wires used in the fatigue test are: a tungsten alloy wire (ReW wire) having a Re content of 1 wt %, a pure tungsten wire (pure W wire), and a piano wire as a comparative example. Note that the pure tungsten wire is a tungsten wire having a sufficiently high content of tungsten, i.e., a tungsten content of 99.95 wt % or more.

Table 1 below shows the physical property values, test conditions, and test results of the tungsten alloy wire and the piano wire that were used.

TABLE 1

| | | | | | | | | | Test result |
|---|---|---|---|---|---|---|---|---|---|
| | Physical property values of metal wire | | | | Test conditions | | | | Total |
| | | | Wire | Tensile | | | Maximum | Stress | number |
| | | Porosity | strength | strength | Load [N] | Load | stress | amplitude | of cycles |
| | Sample | [%] | [N] | [MPa] | (single wire) | [N] | [MPa] | [MPa] | [cycles] |
| Working Example 1 | 1% ReW | 0.25 | 5.725 | 5,100 | 5 | 10 | 4,400 | 1,980 | 21,288 |
| | 1% ReW | 0.25 | 5.725 | 5,100 | 6 | 12 | 5,300 | 2,385 | 609 |
| | 1% ReW | 0.25 | 5.725 | 5,100 | 4.75 | 9.5 | 4,200 | 1,890 | 78,224 |
| Working Example 2 | Pure W | 0.18 | 5.218 | 4,800 | 5 | 10 | 4,400 | 1,980 | 61,755 |
| Working Example 3 | 1% ReW | 0.11 | 5.532 | 4,900 | 5 | 10 | 4,400 | 1,980 | 89,370 |
| Working Example 4 | 1% ReW | 0.07 | 5.542 | 4,900 | 5 | 10 | 4,400 | 1,980 | 100,000 |
| | Piano wire | | 5.170 | 4,800 | 5 | 10 | 4,400 | 1,980 | 228 |
| | Piano wire | | 5.170 | 4,800 | 3.5 | 7 | 3,100 | 1,395 | 704 |
| | Piano wire | | 5.170 | 4,800 | 2.5 | 5 | 2,200 | 990 | 1,320 |
| | Piano wire | | 5.170 | 4,800 | 2 | 4 | 1,800 | 810 | 1,565 |
| | Piano wire | | 5.170 | 4,800 | 1 | 2 | 900 | 405 | 5,512 |
| | Piano wire | | 5.170 | 4,800 | 1 | 2 | 900 | 405 | 21,746 |
| | Piano wire | | 5.170 | 4,800 | 1 | 2 | 900 | 405 | 15,846 |

The diameter of each of the ReW wire, the pure W wire, and the piano wire is approximately 37 μm. The cross-sectional area of each of the ReW wire, the pure W wire, and the piano wire is approximately 0.0022 mm².

In Table 1, “Sample” refers to the type of the metal wire subjected to the fatigue test. The “1% ReW” denotes a tungsten alloy wire (ReW wire) having a Re content of 1 wt %. “Pure W” denotes a pure tungsten wire (pure W wire). The “Porosity” is a percentage of porosity in each metal wire. The details of porosity will be described later. “Wire strength” denotes the strength of each metal wire. “Tensile strength” denotes a tensile strength of each metal wire.

“Load” denotes a maximum load applied to jig 20 vertically upward by hoisting tool 50 illustrated in FIG. 2. “Load (single wire)” denotes a load applied to a single metal wire. As illustrated in FIG. 2, the metal wire is wrapped around the two jigs 20 and 30 to make one round trip between the two jigs 20 and 30. This makes “two” metal wires for convenience. Since the load applied to jig 20 is spread across the “two” metal wires, the load per metal wire is half the load applied to jig 20.

“Maximum stress” is a stress to be applied to each metal wire when a maximum load is applied. “Stress amplitude” denotes a width of change in stress in the fatigue test. As mentioned above, in the fatigue test, the load changes from 10% of the maximum load to the maximum load. Therefore, the stress applied to the metal wire also changes from 10% of the maximum stress (initial stress) to the maximum stress. “Stress amplitude” corresponds to half the difference between the maximum stress and the initial stress.

“Number of cycles” denotes a total number of repetitions required to fracture the metal wire as a result of the fatigue test.

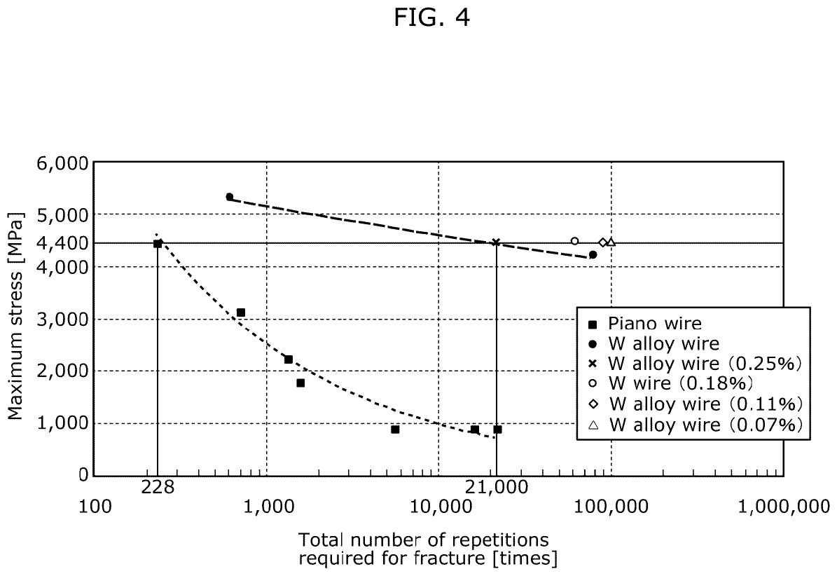

FIG. 4 is a graph showing results of the fatigue test. In FIG. 4, the vertical axis represents the maximum stress applied to the metal wire in the fatigue test. The horizontal axis represents a total number of repetitions of the fatigue test that is required to fracture the metal wire. In other words, the metal wire is less likely to fracture and is more durable as the value is located more right side of the graph. Note that the graph in FIG. 4 shows that 1 million cycles is the maximum cycles of the fatigue test, but the maximum cycles of the fatigue test that was actually conducted is 100,000 cycles.

As shown in FIG. 4, the total number of repetitions of the fatigue test increases as the maximum stress becomes smaller regarding both the piano wire and the tungsten alloy wire. When the maximum stress is 4400 MPa, the total number of repetitions of the fatigue test for the piano wire was 228 times. In contrast, regarding the tungsten alloy wire or the pure tungsten wire, the total number of repetitions was 20,000 times or more, more specifically, 21,288 times or more. In other words, it can be understood that the tungsten alloy wire or the pure tungsten wire has approximately 100 times or more durability than the piano wire does.

Even when the maximum stress was lowered to 900 MPa, the piano wire fractured at 5512, 15,846, or 21,746 times. Furthermore, if the maximum stress is lowered, it can be inferred that the total number of repetitions is likely to increase, but it is not suitable for use as a saw wire compared with the tungsten alloy wire. In other words, even if the maximum stress to be applied to the saw wire is small, such as when a soft ingot is cut, the total number of repetitions of the test of the piano wire is not sufficient. Therefore, the piano wire is not only difficult to be reused, but also may break when cutting an ingot, making it unsuitable for a saw wire compared with the tungsten alloy wire.

In contrast, regarding the tungsten alloy wire, increase in the total number of repetitions relative to the reduction in the maximum stress is large. In other words, even a slight decrease in the maximum stress will greatly increase the total number of repetitions. Therefore, the possibility of reuse can be further increased by reducing the stress when cutting ingot 5.

Note that in the results of the fatigue test, a result of only one sample is shown regarding the pure tungsten wire, but effects equivalent to those of the tungsten alloy wire can be obtained. Also, in the case of the tungsten alloy wire, equivalent effects can be obtained with metals other than rhenium (for example, osmium).

### [Relationships Between Porosity and Test Results]

As described above, metal wire 1 according to the present embodiment has higher durability and can be reused after metal wire 1 is used as saw wire 3, compared with the piano wire. The inventors of the present application have found significant relationships between the porosity in metal wire 1 and the durability (number of repetitions). The following describes the relationships between the porosity of metal wire 1 and the test results of the fatigue test.

Porosity is a percentage of voids included in metal wire 1. More specifically, porosity indicates a percentage of an area occupied by a void per a predetermined unit area in a cross section of metal wire 1. Porosity can be calculated by observing a cross-sectional image of metal wire 1 produced by a scanning electron microscope (SEM).

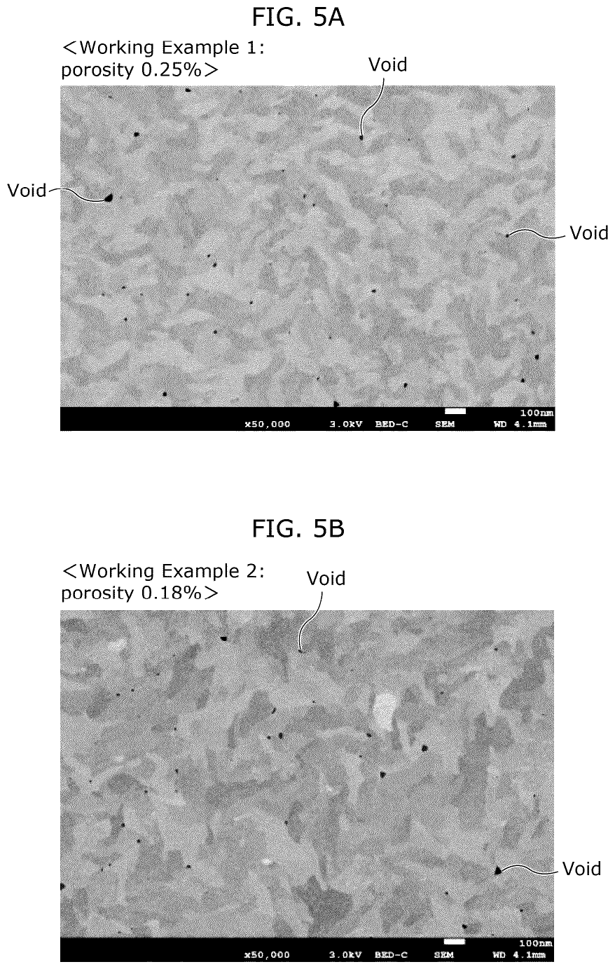

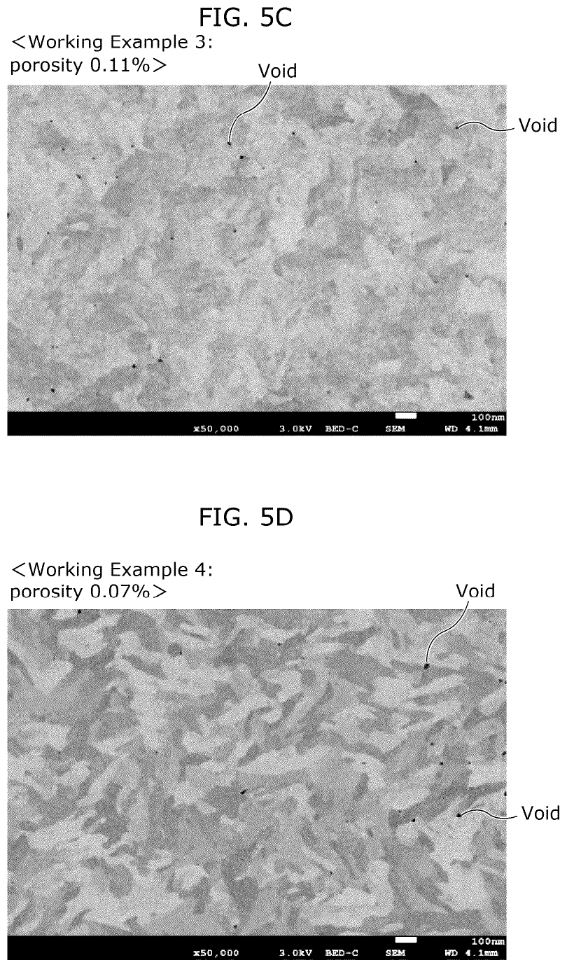

FIG. 5A to FIG. 5D are cross-sectional views of metal wires according to Working Examples 1 to 4 in Table 1, respectively. As shown in each figure, each of the black parts is a void. The voids are mainly located at grain boundaries. The porosity of metal wires according to Working Examples 1 to 4 decreases in this order.

In Working Examples 1 to 4, samples that have undergone a fatigue test at a maximum stress of 4400 MPa was used. As shown in Table 1 and FIG. 4, the total number of repetitions of the fatigue test increases as the porosity decreases. That is, the durability of metal wire 1 is higher as the porosity decreases.

More specifically, as shown in Working Example 1, it can be understood that if the porosity of metal wire 1 is 0.25% or less, metal wire 1 has approximately 100 times or more durability than the piano wire does. If the porosity of metal wire 1 is 0.18% or less, metal wire 1 has approximately three times or more durability than in the case where the porosity is 0.25%. In addition, if the porosity of metal wire 1 is 0.11% or less, metal wire 1 has approximately four times or more durability than in the case where the porosity is 0.25%. It can be understood that when the porosity of metal wire 1 is 0.07%, metal wire 1 is extremely durable and does not fracture even after 100,000 cycles of the fatigue test. The porosity of metal wire 1 may be less than 0.07%.

### [Manufacturing Method]

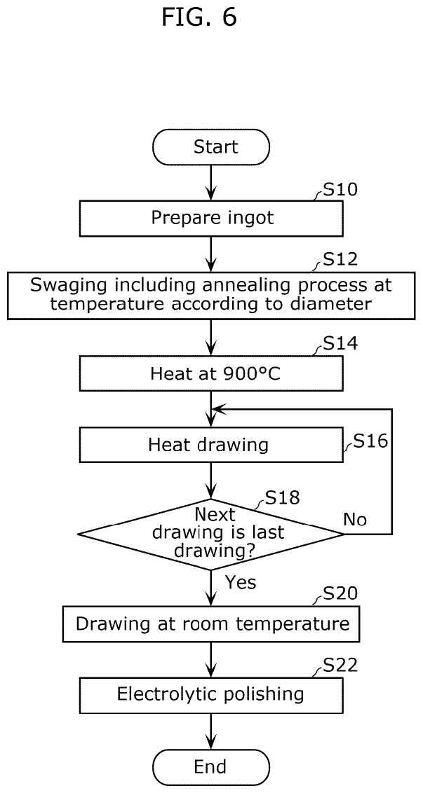

Next, a method of manufacturing the metal wire according to the present embodiment will be described with reference to FIG. 6. FIG. 6 is a flowchart illustrating a method of manufacturing the metal wire according to the present embodiment.

As illustrated in FIG. 6, firstly, a tungsten ingot is prepared (S10). More specifically, a tungsten ingot is produced by preparing an aggregate of tungsten powder and pressing and sintering the prepared aggregate.

Note that when metal wire 1 containing a tungsten alloy is manufactured, a mixture of tungsten powder and metal powder (for example, rhenium powder) mixed in a predetermined proportion is prepared instead of an aggregate of tungsten powder. The average particle size of tungsten powder and rhenium powder may be in a range of, for example, but not limited to, from at least 3 μm to at most 4 μm.

Next, swaging processing is performed on the produced tungsten ingot (S12). More specifically, the tungsten ingot is press-forged from its periphery and extended to be a tungsten wire having a wire shape. Instead of the swaging processing, the tungsten ingot may be subjected to rolling processing. For example, by repeatedly applying the swaging processing to the tungsten ingot, a tungsten ingot having a diameter of approximately 15 mm is shaped into a tungsten wire having a diameter of approximately 3 mm. Annealing processing is performed during an intermediate process of the swaging processing to ensure workability in the subsequent processes. By adjusting the annealing conditions at this time, it is possible to manufacture metal wire 1 having different porosity described above. Specific annealing conditions will be described later.

Next, prior to heat drawing, the tungsten wire is heated at 900° C. (S14). More specifically, the tungsten wire is directly heated by a burner, for example. An oxide layer is formed on the surface of the tungsten wire by heating the tungsten wire, to prevent breakage of the tungsten wire during the processing in the subsequent heat drawing.

Next, heat drawing is performed (S16). More specifically, drawing of the tungsten wire, namely, a wire drawing process (thinning) of the tungsten wire, is performed using one wire drawing die, while the tungsten wire is being heated. The heating temperature is, for example, 1000° C. The workability of a tungsten wire is enhanced as the heating temperature increases, and thus it is possible to easily perform drawing. The reduction in area of the tungsten wire by one drawing using a single wire drawing die is, for example, at least 10% and at most 40%. In the drawing process, a lubricant including graphite dispersed in water may be used.

After the drawing process, the surface of the tungsten wire may be smoothed by performing electrolytic polishing. Electrolytic polishing is performed, for example, by immersing the tungsten wire and a counter electrode in an electrolyte solution, such as a sodium hydroxide aqueous solution, and causing a potential difference between the tungsten wire and the counter electrode.

The heat drawing (S16) is repeated until a tungsten wire having a desired diameter is obtained (No in S18). The desired wire diameter here is a diameter immediately before the last drawing process (S20) is performed, and is, for example, at most 250 μm.

In the repeating of heat drawing, a wire drawing die having a smaller pore diameter than a pore diameter of a wire drawing die used in the immediately preceding drawing is used. Moreover, in the repeating of heat drawing, the tungsten wire is heated at a heating temperature lower than a heating temperature used in the immediately preceding drawing. For example, the heating temperature in the drawing process immediately before the final drawing process is lower than any previous heating temperatures, and is, for example, 400° C., which contributes to refinement of crystal grains. Note that the heating temperatures in the heat drawing are adjusted such that the amount of oxide adhering to the surface of the tungsten wire is in a range of from at least 0.8 wt % to at most 1.6 wt % of the tungsten wire, for example. In the repeating of heat drawing, electrolytic polishing may be omitted.

Drawing at room temperature (S20) is performed when a tungsten wire having a desired diameter is obtained and the next drawing process is the last drawing process (Yes in S18). In other words, by drawing the tungsten wire without heating, the crystal grains are further refined. Moreover, it also has an effect of aligning the crystal orientation in the processing axis direction (more specifically, the direction parallel to the axis of the tungsten wire) by drawing at room temperature. Room temperature is, for example, a temperature in a range of from at least 0° C. to at most 50° C., and is 30° C. as one example. More specifically, the tungsten wire is drawn using a plurality of wire drawing dies having different pore diameters.

In the drawing at room temperature, a liquid lubricant such as a water-soluble lubricant is used. Since heating is not carried out in the drawing at room temperature, liquid evaporation is inhibited. Accordingly, a sufficient function as a lubricant can be exerted. In contrast to the heat drawing at 600° C. or higher which is a traditional tungsten wire processing method conventionally performed, the tungsten wire is not heated and is processed while being cooled with the liquid lubricant. As a result, it is possible to inhibit dynamic recovery and dynamic recrystallization, contribute to the refinement of crystal grains without breakage, and achieve a high tensile strength.

Lastly, electrolytic polishing is performed on the tungsten wire having a desired diameter resulting from the drawing at room temperature (S22). Electrolytic polishing is performed, for example, by immersing the tungsten wire and a counter electrode in an electrolyte solution, such as a sodium hydroxide aqueous solution, and causing a potential difference between the tungsten wire and the counter electrode.

Through the above-described processes, metal wire 1 according to the present embodiment is manufactured. Through the above-described manufacturing processes, metal wire 1 immediately after manufacturing has a length of, for example, at least 50 km, and thus is industrially available. Metal wire 1 is cut to a suitable length according to the aspect in which metal wire 1 is to be used, and can also be used in a shape of a needle or a stick.

Note that, each of the processes described in the method of manufacturing metal wire 1 is performed, for example, in-line. More specifically, the plurality of wire drawing dies used in step S16 are arranged in order of decreasing pore diameter in the production line. In addition, a heating device such as a burner is disposed between the respective wire drawing dies. In addition, an electrolytic polishing device may be disposed between the respective wire drawing dies. The plurality of wire drawing dies used in step S20 are arranged in order of decreasing pore diameter on the downstream side (i.e., the subsequent-process side) of the wire drawing dies used in step S16, and the electrolytic polishing device is disposed on the downstream side of the wire drawing die having the smallest pore diameter. Note that each of the processes may be individually performed.

The annealing conditions in the swaging process (S12) for adjusting porosity will be described below with reference to Table 2.

TABLE 2

| | First annealing | Second annealing | |
|---|---|---|---|
| | temperature | temperature | |
| | [° C.] (Diameter | [° C.] (Diameter | Porosity |
| | of 11-12 mm) | of 5-8 mm) | [%] |
| Working Example 1 | 1800-1900 | 1800-1900 | 0.25 |
| Working Example 2 | 2000-2100 | 1600-1700 | 0.18 |
| Working Example 3 | 2000-2100 | 1600-1700 | 0.11 |
| Working Example 4 | 2000-2100 | 1600-1700 | 0.07 |

The swaging processing is performed in stages a plurality of times according to the diameter of the tungsten wire to be processed. At this time, annealing is performed to improve the tensile strength and the workability in the subsequent drawing process.

As shown in Table 2, in Working Example 1, when the diameter of a metal wire is in a range of from at least 11 mm to at most 12 mm, annealing is performed on the metal wire at a temperature in a range of from at least 1800° C. to at most 1900° C. Tungsten recrystallizes when annealed at a temperature greater than 2000° C. The tensile strength of metal wire 1, which is a final product, can be increased by performing annealing under conditions in which tungsten does not recrystallize. As shown in Table 1, the tensile strength of the ReW wire according to Working Example 1 can be made higher than the tensile strength of the pure tungsten wire according to Working Example 2 and the tensile strength of each of the ReW wires according to Working Examples 3 and 4.

Next, in Working Example 1, when the diameter of a metal wire is in a range of from at least 5 mm to at most 8 mm, annealing was performed on the metal wire at a temperature in a range of from at least 1800° C. to at most 1900° C. By performing annealing at a temperature in a range where recrystallization does not occur, it is possible to improve workability in subsequent processes without significantly reducing the strength.

In Working Examples 2 to 4, when the diameter of a metal wire is in a range of from at least 11 mm to at most 12 mm, annealing is performed on the metal wire at a temperature in a range of from at least 2000° C. to at most 2100° C. Since the temperature is 2000° C. or higher, tungsten recrystallization occurs, and thus the existing voids move to grain boundaries. Here, the grain size due to recrystallization can be suppressed to approximately 100 μm in the pure tungsten wire according to Working Example 2 by not setting the temperature too high at 2100° C. or lower. This makes it possible to form many grain boundaries and disperse voids in the tungsten wire. Moreover, in the ReW wire according to Working Examples 3 and 4, the grain diameter due to recrystallization is suppressed to approximately 50 μm. Therefore, more voids can be dispersed. In the subsequent swaging processing, the voids can be released to the outside of the tungsten wire through grain boundaries, and thus the porosity can be reduced. In Working Examples 3 and 4, the porosity can be made lower than in the case of Working Example 2 because the dispersion state of the porosity is good. Note that the difference in porosity in Working Examples 3 and 4 is due to variations in production or measurement of porosity.

In Working Examples 2 to 4, when the diameter of a metal wire is in a range of from at least 5 mm to at most 8 mm, annealing is further performed on the metal wire at a temperature in a range of from at least 1600° C. to at most 1700° C. By performing annealing at a temperature in a range where recrystallization does not occur, it is possible to improve workability in subsequent processes without reducing the strength. Note that in Working Examples 2 to 4, the temperature in a first annealing is higher than in the temperature in Working Example 1. Therefore, the temperature in a second annealing is set lower than in the case of Working Example 1. This ensures the tensile strength of 4800 MPa or more for metal wire 1 according to Working Examples 2 to 4.

### Advantageous Effects, Etc.

As described above, metal wire 1 according to the present embodiment includes: tungsten or a tungsten alloy. When a fatigue test is conducted on metal wire 1 according to the present embodiment at a maximum stress of 4400 MPa in accordance with Japanese Industrial Standard (JIS) C6821, a total number of cycles required to break metal wire 1 is at least 20,000 cycles.

With this, a highly durable metal wire 1 can be achieved. For example, if metal wire 1 is used as saw wire 3, metal wire 1 can be reused.

In addition, for example, a total number of cycles required to break metal wire 1 is at least 60,000 cycles.

With this, the durability of metal wire 1 is even higher, and thus it is more effective for reuse and so on.

Moreover, for example, a porosity of tungsten in metal wire 1 is at most 0.25%.

With this, the durability of metal wire 1 can be increased.

Moreover, for example, metal wire 1 has a tensile strength of at least 4.8 GPa.

With this, metal wire 1 (saw wire 3) can be stretched more strongly on the guide roller, and thus the oscillation width of metal wire 1 can be reduced. By reducing the oscillation width of metal wire 1, the cutting allowance of an object to be cut decreases. This makes it possible to reduce a kerf loss of the object to be cut.

Moreover, for example, saw wire 3 according to the present embodiment includes metal wire 1 and abrasive particles 2 electrodeposited on a surface of metal wire 1.

With this, a highly durable saw wire 3 can be achieved. For example, saw wire 3 used for cutting ingot 5 can be reproduced by peeling off abrasive particles 2 and the plating layer from saw wire 3 and then electrodepositing abrasive particles 2 on saw wire 3.

### Others

The foregoing has described the metal wire and the saw wire according to the present invention based on the embodiment, but the present invention should not be limited to the embodiment described above.

For example, saw wire 3 does not need to include the electrodeposited abrasive particles 2. For example, saw wire 3 may include only metal wire 1 and may be used for a cutting device of a loose abrasive type.

Moreover, for example, the tungsten content of metal wire 1 may be less than 90 wt %. For example, the tungsten content of metal wire 1 is greater than 50 wt %. The tungsten content of metal wire 1 may be at least 70 wt %, at least 75 wt %, at least 80 wt %, or 85 wt %.

Moreover, for example, in the above embodiment, metal wire 1 may be doped with a minute amount of potassium, etc. Doped potassium is present at the crystal grain boundaries of tungsten. The potassium (K) content is, for example, at most 0.010 wt/c. A potassium doped tungsten wire can also achieve a metal wire having a higher tensile strength than a general tensile strength of a piano wire, as with the tungsten alloy wire. Similar effects can be obtained not only with oxides of potassium but also with oxides of other substances, such as cerium or lanthanum.

Moreover, for example, metal wire 1 may be used for other purposes in addition to saw wire 3. For example, metal wire 1 may be used for other purposes, such as metal mesh, or stranded wire or rope.

Additionally, embodiments arrived at by those skilled in the art making various modifications to the above embodiment, as well as embodiments arrived at by combining structural elements and functions described in the above embodiment in any manner without materially departing from the teachings of the present invention are intended to be included within the scope of the present invention.

### REFERENCE SIGNS LIST

1 metal wire
2 abrasive particles
3 saw wire

1. A metal wire comprising:
tungsten or a tungsten alloy, wherein
when a fatigue test is conducted on the metal wire at a maximum stress of 4400 MPa in accordance with Japanese Industrial Standard (JIS) C6821, a total number of cycles required to break the metal wire is at least 20,000 cycles.

2. The metal wire according to claim 1, wherein
when a fatigue test is conducted on the metal wire at a maximum stress of 4400 MPa in accordance with Japanese Industrial Standard (JIS) C6821, a total number of cycles required to break the metal wire is at least 60,000 cycles.

3. The metal wire according to claim 1, wherein
a porosity of tungsten in the metal wire is at most 0.25%.

4. The metal wire according to claim 1, wherein
the metal wire has a tensile strength of at least 4.8 GPa.

5. A saw wire comprising:
the metal wire according to claim 1; and
abrasive particles electrodeposited on a surface of the metal wire.
